(19) United States
(12) Patent Application Publication
(10) Pub. No.: US 2012/0026653 A1
(43) Pub. Date: Feb. 2, 2012

(54) PLASTIC HOUSING FOR LIQUID CRYSTAL DISPLAY, MANUFACTURING METHOD THEREOF AND LIQUID CRYSTAL DISPLAY

(75) Inventor: Gege Zhou, Guangdong (CN)

(73) Assignee: SHENZHEN CHINA STAR OPTOELECTRONICS TECHNOLOGY CO., LTD., Shenzhen (CN)

(21) Appl. No.: 12/996,323

(22) PCT Filed: Sep. 2, 2010
(86) PCT No.: PCT/CN10/76565

§ 371 Date: Dec. 3, 2010

(30) Foreign Application Priority Data
Jul. 29, 2010 (CN) 201010245345.5

(51) Int. Cl. H05K 5/02; B29C 45/00; A47B 81/00

(52) U.S. Cl. 361/679.01; 312/223.1; 264/328.14

(57) ABSTRACT

A plastic housing for a liquid crystal display, a manufacturing method thereof and the liquid crystal display are provided, and the plastic housing is an integral plastic housing, including a lower supporting surface and two side frames oppositely disposed on the lower supporting surface. Each of the two side frames is formed with a shoulder on an inner sidewall thereof. The shoulder has a first planar surface parallel to the lower supporting surface. The shoulder further has a second planar surface perpendicular to the lower supporting surface. The height of the second planar surface is equal to or greater than the thickness of a plurality of optical films. The advantage of the present invention is to employ the integral plastic housing to install the optical films and the panel. The integral plastic housing includes two side frames with the shoulders, so that the optical films and the panel can be commonly assembled together with the integral plastic housing. When needing to replace the backlight source, the optical films and the panel can be commonly disassembled together with the integral plastic housing. Therefore, the optical films can be conveniently and speedily disassembled and assembled and it can avoid being polluted during disassembly and assembly. Moreover, the optical films can be more easily fixed because of the embedded engagement effect of the integral plastic housing.

### BACKGROUND OF THE INVENTION

1. Field of the Invention

The present invention relates to a manufacture field of a liquid crystal display, and more particularly to a plastic housing for a liquid crystal display, a manufacturing method thereof and the liquid crystal display.

2. Description of the Prior Art

A liquid crystal display (LCD) is a flat panel display device, which can display images by liquid crystals. Comparing with other display devices, the liquid crystal display has many advantages of light and thin scale, low driving voltage and low power consumption, so that it is widely used in the whole industry. However, because the liquid crystal display panel cannot emit light by self, it needs to employ a backlight assembly to provide an independently artificial backlight source.

At present, the backlight source mainly adopts a cold cathode fluorescent lamp (CCFL) light and a light emitting diode (LED) light, both of which can be used as two backlight modes: a side backlight mode and a bottom backlight mode. Comparing with the CCFL light, the LED light has many advantages of energy saving, long lifespan, and small size, so that it is regarded as a trend of a liquid crystal display television.

The backlight assembly not only includes the backlight source as described above, but also includes a back plate, optical films, a plastic housing, a front frame and so on. During assembling, the backlight source is first mounted on the back plate, and then the optical films are installed. Next, the plastic housing is mounted, and finally the front frame is covered.

FIG. 1 is a schematic view of location relationship between a plastic housing 12 and a plurality of optical films 11 in the prior art. When assembling, the optical films 11 are firstly used to cover on a backlight source (not shown in FIG. 1). Then, the plastic housing 12 is used to enclose the optical films 11. The optical films 11 include many important optical components, such as a diffusion plate and a light guide plate. If the backlight source or any other component located under the optical films 11 is destroyed and needs to be replaced, it is needed to firstly remove the plastic housing 12, and then remove the optical films 11. The optical films 11 in FIG. 1 are mainly a light guide plate and a diffusion plate, and the thickness of the optical films 11 is generally 3 to 4 millimeters.

The structure of the backlight module in the prior art is bad for being disassembled or repaired. During detaching, it is necessary to firstly detach the plastic housing 12, and then independently detach the optical films 11. The optical films 11 are easily polluted due to being touched. Once the optical films 11 served as the main component of the liquid crystal display are polluted, it will influence the backlight uniformity and the yield rate of the liquid crystal display, resulting in a considerable inconvenience and loss of manufacture or repair.

### BRIEF SUMMARY OF THE INVENTION

To solve the foregoing technical problems, an object of the present invention is to provide a plastic housing for a liquid crystal display, a manufacturing method thereof and the liquid crystal display.

To solve the foregoing technical problems, the present invention provides a plastic housing for a liquid crystal display. The plastic housing is an integral plastic housing, comprising a lower supporting surface and two side frames being oppositely disposed on the lower supporting surface. Each of the two side frames is formed with a shoulder on an inner sidewall thereof. The shoulder has a first planar surface parallel to the lower supporting surface, and the first planar surface is used to support a panel of the liquid crystal display. The shoulder further has a second planar surface perpendicular to the lower supporting surface. The height of the second planar surface is equal to or greater than the thickness of a plurality of optical films. The second planar surface and the lower supporting surface commonly define a receiving space for receiving the optical films of the liquid crystal display.

As a selectable technical solution, the second planar surface is further formed with an engaging block, which is protruded on the second planar surface. A distance between the engaging block and the lower supporting surface is equal to the height of the second planar surface, and is equal to or greater than the thickness of the optical films, so that the optical films can be tightly engaged in the receiving space commonly defined by the second planar surface and the lower supporting surface.

As a selectable technical solution, the optical films are selected from a diffusion sheet, a prismatic lens, a microlens sheet, a lenticular lens or a combination thereof. The thickness of each of the optical films is 0.2 to 0.3 millimeters, such as 0.25 millimeters.

The present invention further provides a manufacturing method of a plastic housing, wherein the plastic housing is an integral plastic housing, comprising: providing a mould for molding, which includes a first mould core, a second mould core and a third mould core, wherein the first and second mould cores are opposite to each other for clamping the third mould core, and outer sidewalls of the first and second mould cores have configurations respectively matched with inner sidewalls of the integral plastic housing; injecting melt material into the mould and cooling for forming the integral plastic housing; taking out the third mould core clamped between the first and second mould cores; and moving the first and second mould cores toward each other to separate the outer sidewalls thereof from the inner sidewalls of the formed integral plastic housing, and then taking out the first and second mould cores.

As a selectable technical solution, the cross section of the third mould core is trapezoid, the shorter one of two bottom sides of which is in contact with the formed integral plastic housing, and two lateral sides of which are in contact with the first and second mould cores, respectively.

The present invention further provides a liquid crystal display comprising: a plurality of optical films, a plastic housing and a panel, wherein the plastic housing is an integral plastic housing, and comprises a lower supporting surface and two side frames oppositely disposed on the lower supporting surface. Each of the two side frames is formed with a shoulder on an inner sidewall thereof. The shoulder has a first planar surface parallel to the lower supporting surface. A panel is placed on the first planar surface, and two ends of the panel are separately clamped by the inner sidewalls of the two side frames. The shoulder further has a second planar surface perpendicular to the lower supporting surface. The height of the second planar surface is equal to or greater than the thickness of a plurality of optical films. And the optical films are installed in a receiving space commonly defined by the second planar surface and the lower supporting surface.

As a selectable technical solution, the second planar surface is further formed an engaging block, which is protruded on the second planar surface. A distance between the engaging block and the lower supporting surface is equal to or greater than the thickness of the optical films, so that the optical films can be tightly engaged in the receiving space commonly defined by the second planar surface and the lower supporting surface.

As a selectable technical solution, the above optical films are selected from a diffusion sheet, a prismatic lens, a microlens sheet, a lenticular lens and a combination thereof. Each of the thickness of each of the optical films is 0.2 to 0.3 millimeters, such as 0.25 millimeters.

The advantage of the present invention is to employ the integral plastic housing to install the optical films and the panel. The integral plastic housing includes two side frames with the shoulders, so that the optical films and the panel can be commonly assembled together with the integral plastic housing. When needing to replace the backlight source, the optical films and the panel can be commonly disassembled together with the integral plastic housing. Therefore, the optical films can be conveniently and speedily disassembled and assembled and it can avoid being polluted during disassembly and assembly. Moreover, the optical films can be more easily fixed because of the embedded engagement effect of the integral plastic housing. The present invention further provides a method for manufacturing the integral plastic housing is particularly suitable to be applied to the manufacture of the above integral plastic housing.

### BRIEF DESCRIPTION OF THE DRAWINGS

FIG. 1 is a schematic view of location relationship between a plastic housing and a plurality of optical films in the prior art;

FIG. 2 is a structure schematic view of an integral plastic housing and peripheral components of a liquid crystal display of the present invention;

FIG. 3 is an enlarged view of a left shoulder of FIG. 2;

FIG. 4 is a structure schematic view of a sidewall of the integral plastic housing provided by the present invention;

FIG. 5 is a flow chart of a manufacturing method of the integral plastic housing provided by the present invention; and

FIG. 6 is a schematic view of location relationship between the structures of a first mould core, a second mould core and a third mould core employed by steps of FIG. 5 and the formed integral plastic housing.

### DETAILED DESCRIPTION OF THE PREFERRED EMBODIMENTS

The following text with reference to the accompanying drawings is a detail description for the specific embodiment of a plastic housing for a liquid crystal display, a manufacturing method thereof and the liquid crystal display provided by the present invention.

For more clearly and easily understanding the object, the feature and the advantage of the present invention, the preferred embodiments with reference to the accompanying drawings now have been given for detail describing the technical features of the different embodiments of the present invention, wherein the configurations of all elements of the embodiments are intended to illustrate, but not to limit, the present invention. The labels of the elements of the different embodiments are partially repeated in the figures for simplifying the description and not intently indicating that the different embodiments have relevance.

FIG. 2 is a structure schematic view of an integral plastic housing and peripheral components of a liquid crystal display of the present invention, comprising a plurality of optical films 30, an integral plastic housing 20 and a panel 40. The integral plastic housing 20 has a lower supporting surface 21 and two side frames 22, 23, wherein the two side frames 22, 23 are opposite to be disposed on two ends of the lower supporting surface 21. Inner sidewalls of the two side frames 22, 23 are formed with two shoulders 24, 25, which are separately protruded inward from the inner sidewalls. The two shoulders 24, 25 are used to support the panel 40.

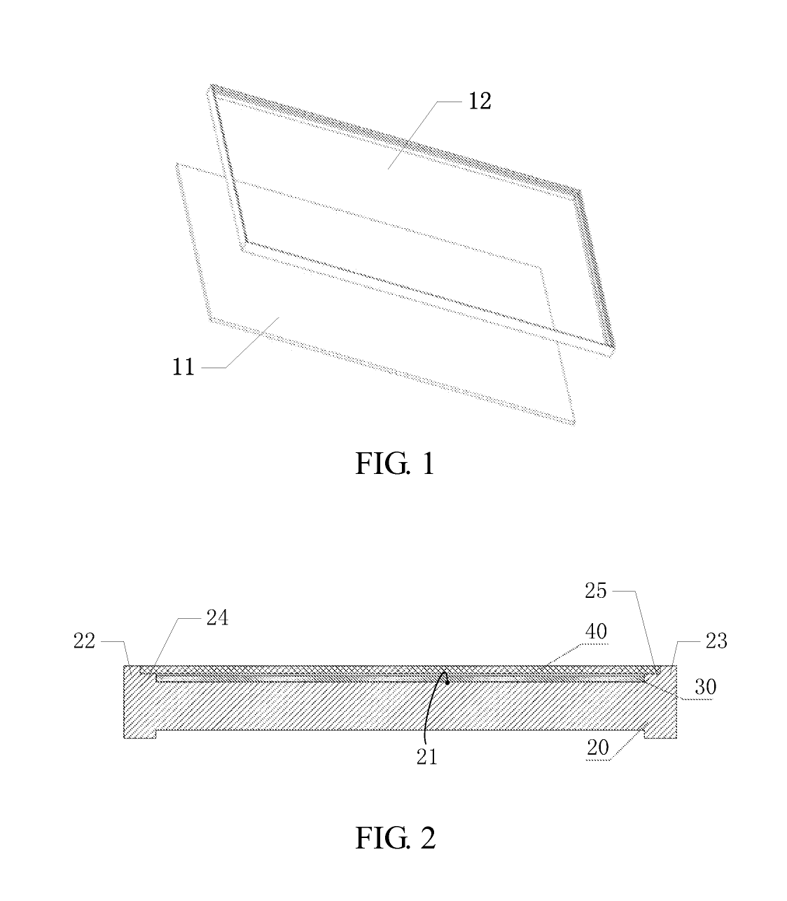

The integral plastic housing 20 should include a plastic housing 12 and a plurality of optical films 11, which are shown in FIG. 1. By adopting a mould to perform an integral forming process of injection molding, the edges of the optical film 11 are connected with the corresponding edges of the plastic housing 12, so that the foregoing two parts are combined to form a single part as the integral plastic housing 20 shown in FIG. 2.

The optical films 30 mainly include a diffusion sheet, a prismatic lens, a microlens sheet, a lenticular lens and so on, or a combination thereof (being different from the optical films of FIG. 1). The thickness of each of the optical films 30 is generally 0.2 to 0.3 millimeters, for example, generally about 0.25 millimeters. The optical films 30 herein should include multi-sheet optical films, so the thickness of the optical films 30 is generally 0.8 to 1.2 millimeters.

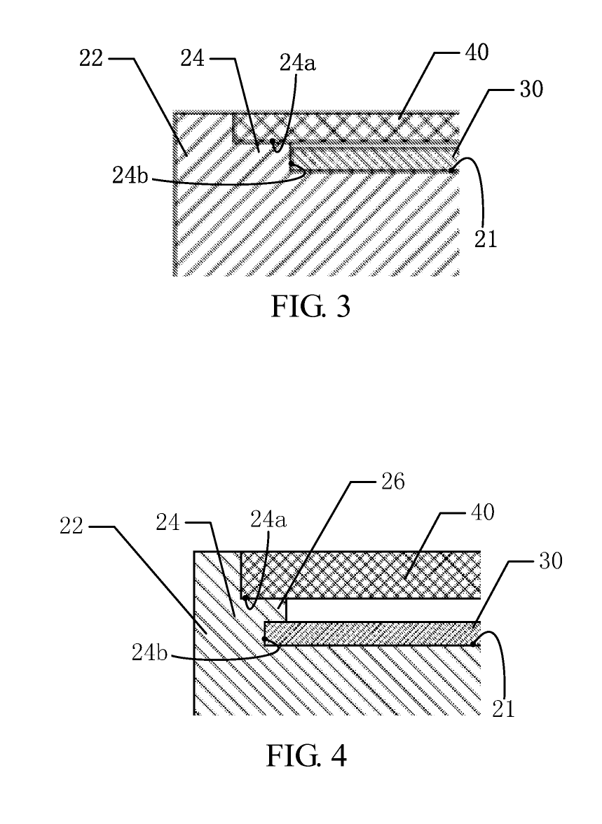

FIG. 3 is an enlarged view of the left shoulder 24 in FIG. 2. The right shoulder 25 is symmetrical to the left shoulder 24 of FIG. 3, so the structure of the right shoulder 25 is not drawn individually. The shoulder 24 has a first planar surface 24a parallel to the lower supporting surface 21. The panel 40 is parallel placed on the first planar surface 24a and a first planar surface of the right shoulder 25. Two ends of the panel 40 are separately and tightly clamped by the inner sidewalls of the two side frames 22, 23.

The left shoulder 24 has a second planar surface 24b perpendicular to the lower supporting surface 21. The second planar surface 24b, a second planar surface of the right shoulder 25, and the lower supporting surface 21 commonly define a receiving space. The optical films 30 can be fixed in the receiving space. Therefore, in this embodiment, the height of the second planar surface 24b is equal to the distance between the first planar surface 24a and the lower supporting surface 21, and the distance is equal to or greater than the thickness of the optical films 30 for ensuring to contain the optical films 30 and ensuring that the optical films 30 are not in contact with the panel 40 placed on the first planar surface 24a.

It can be seen from FIGS. 2 and 3, because the integral plastic housing 20 employs the shoulders 24, 25 to retain the optical films 30 and the panel 40, the optical films 30 can be tightly clamped in the integral plastic housing 20 by the embedded mode, and the panel 40 covers the optical films 30. When disassembling, it only needs to take out the integral plastic housing 20, wherein the optical films 30 and the panel 40 also can be simultaneously taken out together with the integral plastic housing 20, so as to avoid from contacting and polluting the optical films 30 during disassembly and assembly.

FIG. 4 is a structure schematic view of the sidewall of the integral plastic housing provided by the present invention, in this embodiment, also comprising a lower supporting surface 21 and a side frame 22 disposed on the lower supporting surface 21. The side frame 22 is formed with a shoulder 24, which is protruded on the inner sidewall thereof. The shoulder 24 has a first planar surface 24a parallel to the lower supporting surface 21 and a second planar surface 24b perpendicular to the lower supporting surface 21. Besides, the difference from the foregoing embodiment is that the structure shown in FIG. 4 further comprises an engaging block 26 disposed on the second planar surface 24b, and the engaging block 26 is protruded from the second planar surface 24b. The inner sidewall of the other symmetrical side frame also has a similar structure, which is symmetrical to that shown in FIG. 4. Therefore, the structure of the other symmetrical side frame is not drawn herein. The function of the engaging block 26 is to fix the optical films 30 in a receiving space commonly defined by the second planar surface 24b, a second planar surface located the other end and the lower supporting surface 21 for avoiding it from sliding out of the receiving space. The further function of the engaging block 26 is to separate the optical films 30 and the panel 40 from each other for avoiding from generating the friction due to contact between the optical films 30 and the panel 40 to cause the bad effect. Material of the integral plastic housing is elastic rubber or plastic, so that the optical films 30 can be easily installed into the receiving space. In this embodiment having the engaging block 26, the distance between the engaging block 26 and the lower supporting surface 21 should be controlled to be equal to the height of the second planar surface 24b, and be equal to or slightly greater than the thickness of the optical films 30. The character of this embodiment is that the engaging block 26 can further hold the optical films 30 located on the integral plastic frame 20. The advantage of the distance between the engaging block 26 and the lower supporting surface 21 being slightly greater than the thickness of the optical films 30 is that it needs to reserve an expanding space because the optical films 30 can expand with heat during the working course of the mould. Otherwise, the optical films 30 may be deformed owing to lack of the reserved expanding space, so that affecting the optical quality.

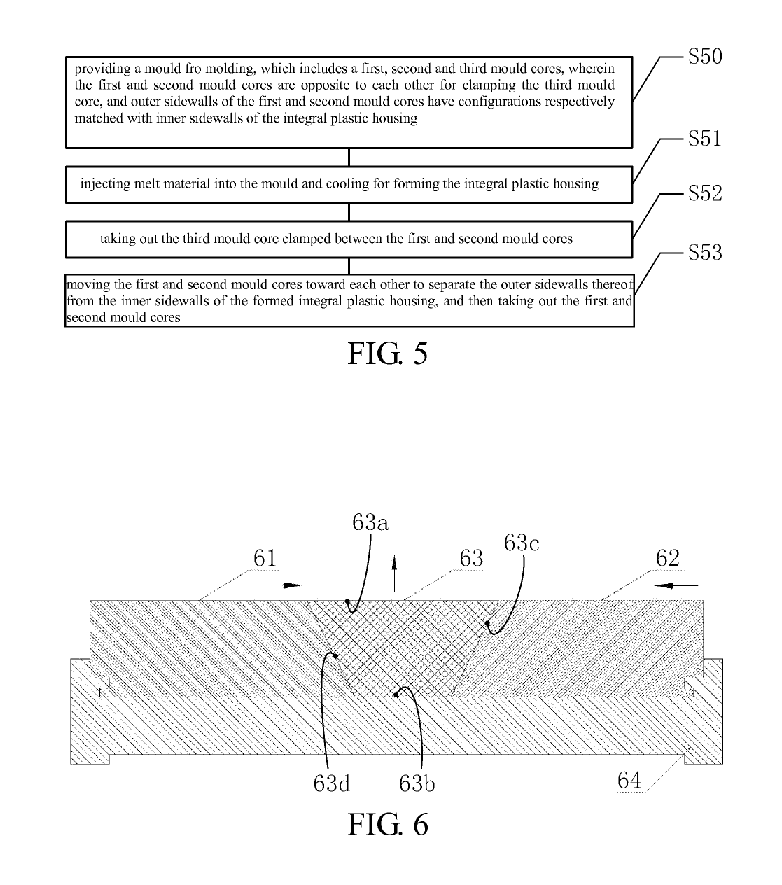

FIG. 5 is a flow chart of a manufacturing method of the integral plastic housing provided by the present invention, comprising: a step S50 for providing a mould for molding, which includes a first, second and third mould cores, wherein the first and second mould cores are opposite to each other for clamping the third mould core, and outer sidewalls of the first and second mould cores have configurations respectively matched with inner sidewalls of the integral plastic housing; a step S51 for injecting melt material into the mould and cooling for forming the integral plastic housing; a step S52 for taking out the third mould core clamped between the first and second mould cores; and a step S53 for moving the first and second mould cores toward each other to separate the outer sidewalls thereof from the inner sidewalls of the integral plastic housing and then taking out the first and second mould cores.

FIG. 6 shows a schematic view of location relationship between the structures of the first mould core 61, the second mould core 62, and the third mould core 63, which are employed by the steps of FIG. 5 and a formed integral plastic housing 64. The formed integral plastic housing 64 is corresponding to the embodiment of the completely integral plastic housing shown in FIG. 4.

Referring to FIG. 6, in the step S50, the mould for molding includes at least one outer mould (not-shown). The outer mould has a mould cavity. The mould cavity contains the first mould core 61, the second mould core 62 and the third mould core 63. The first mould core 61 and the second mould core 62 are opposite to each other for clamping the third mould core 63. In this embodiment, the cross section of the third mould core 63 is trapezoid including an upper bottom side 63a, a lower bottom side 63b and two lateral sides 63c, 63d. The length of the top bottom side 63a is greater than that of the lower bottom side 63b. The lower bottom side 63b is in contact with the formed integral plastic housing 64. The two lateral sides 63c, 63d are separately in contact with the first and second mould cores 61, 62. This arrangement is convenient for separating the third mould core 63 from the mould 60. In other embodiments, the cross section of the third mould core 63 may be rectangular, hemispherical, or other shaped of being capable of ensuring that the third mould core 63 can be smoothly detached from the first and second mould cores 61, 62 under the function of the outer force. The above content disclosed by FIG. 6 should not be understood as limitation to the scope of the present invention.

Continuously referring to FIG. 6, the outer sidewalls of the first and second mould cores 61, 62 have configurations matched with the corresponding inner sidewalls of the integral plastic housing, respectively. In the step S51, the injected melt material can form the inner sidewalls of the integral plastic housing 64 on the surfaces of the mould cores.

Obviously, the above three mould cores 61-63 are mainly used to form the inner sidewalls of the integral plastic housing 64. For forming the complete integral plastic housing 64, the mould 60 also employs other elements besides the three mould cores. This embodiment is mainly explaining the function of the above mould cores during forming the integral plastic housing 64, so that other elements of the mould, such as at least one outer mould having the mould cavity, an ejector element for ejecting the mould and so on, are not shown.

Continuously referring to FIG. 6, after the completion of injecting, it becomes an important problem to solve how separating the above three mould cores 61-63 from the formed integral plastic housing 64. Particularly to the embodiment shown in FIG. 4, because of disposing two engaging blocks 26, the detachability between the mould and the integral plastic housing 64 will be affected. This embodiment employing the above three mould cores arranged in a row can resolve this problem. After the completion of forming, the step S52 is firstly performed for taking out the third mould core 63. After taking out the third mould core 63, the step S53 can be next performed. Because the third mould core 63 between the first mould core 61 and the second mould core 62 has been taken out, a gap is generated, and the first and second mould cores 61, 62 can move toward each other. When the first and second mould cores 61, 62 move toward each other, the outer sidewalls thereof can be separated from the inner sidewalls of the formed integral plastic housing 64, thereby smoothly taking out the first and second mould cores 61, 62.

After the above steps being performed, it need continue to perform an ejecting step for completing the insert molding process of the integral plastic housing.

Processes mentioned above, including the process of injecting the melt material into the mould, the cooling process and the ejection process (but not including the method of taking out the first, second and third mould cores), all adopt the common processes and methods in the art, and so need not be repeated herein.

The above are the preferred embodiment modes, it should be pointed out that any person having ordinary skills in the art also can make many improvement and amendment within the principles of the present invention, and the improvement and amendment also should be considered belonging to the protection scope of the present invention.

What is claimed is:

1. A plastic housing for a liquid crystal display, characterized in that: the plastic housing is an integral plastic housing; the integral plastic housing comprises a lower supporting surface and two side frames being oppositely disposed on the lower supporting surface; each of the two side frames is formed with a shoulder on an inner sidewall thereof; the shoulder has a first planar surface parallel to the lower supporting surface, and the first planar surface is used to support a panel of the liquid crystal display; the shoulder further has a second planar surface perpendicular to the lower supporting surface; the height of the second planar surface is equal to or greater than the thickness of a plurality of optical films; the second planar surface and the lower supporting surface commonly define a receiving space for receiving the optical films; the second planar surface is further formed with an engaging block, which is protruded on the second planar surface; a distance between the engaging block and the lower supporting surface is equal to the height of the second planar surface, and is equal to or greater than the thickness of the optical films, so that the optical films can be tightly engaged in the receiving space commonly defined by the second planar surface and the lower supporting surface; the optical films are selected from a diffusion sheet, a prismatic lens, a microlens sheet, a lenticular lens or a combination thereof; and the thickness of each of the optical films is 0.2 to 0.3 millimeters.

2. A plastic housing for a liquid crystal display, characterized in that: the plastic housing is an integral plastic housing; the integral plastic housing comprises a lower supporting surface and two side frames being oppositely disposed on the lower supporting surface; each of the two side frames is formed with a shoulder on an inner sidewall thereof; the shoulder has a first planar surface parallel to the lower supporting surface, and the first planar surface is used to support a panel of the liquid crystal display; the shoulder further has a second planar surface perpendicular to the lower supporting surface; the height of the second planar surface is equal to or greater than the thickness of a plurality of optical films; and the second planar surface and the lower supporting surface commonly define a receiving space for receiving the optical films of the liquid crystal display.

3. The plastic housing for the liquid crystal display according to claim 2, characterized in that: the second planar surface is further formed with an engaging block, which is protruded on the second planar surface; and a distance between the engaging block and the lower supporting surface is equal to the height of the second planar surface and is equal to or greater than the thickness of the optical films, so that the optical films can be tightly engaged in the receiving space commonly defined by the second planar surface and the lower supporting surface.

4. The plastic housing for the liquid crystal display according to claim 2, characterized in that: the optical films are selected from a diffusion sheet, a prismatic lens, a microlens sheet, a lenticular lens or a combination thereof.

5. The plastic housing for the liquid crystal display according to claim 4, characterized in that: the thickness of each of the optical films is 0.2 to 0.3 millimeters.

6. A manufacturing method of a plastic housing, characterized in that: the plastic housing is an integral plastic housing, comprising:
providing a mould for molding, which includes a first mould core, a second mould core and a third mould core, wherein the first and second mould cores are opposite to each other for clamping the third mould core, and outer sidewalls of the first and second mould cores have configurations respectively matched with inner sidewalls of the integral plastic housing;
injecting melt material into the mould and cooling for forming the integral plastic housing;
taking out the third mould core clamped between the first and second mould cores; and
moving the first and second mould cores toward each other to separate the outer sidewalls thereof from the inner sidewalls of the formed integral plastic housing, and then taking out the first and second mould cores.

7. The manufacturing method of the plastic housing according to claim 6, characterized in that: the cross section of the third mould core is trapezoid, the shorter one of two bottom sides of which is in contact with the formed integral plastic housing, and two lateral sides of which are in contact with the first and second mould cores, respectively.

8. The manufacturing method of the plastic housing according to claim 7, characterized in that: said integral plastic housing comprises said lower supporting surface and two side frames being oppositely disposed on the lower supporting surface; each of the two side frames is formed with a shoulder on an inner sidewall thereof; the shoulder has a first planar surface parallel to the lower supporting surface, and the first planar surface is used to support a panel of a liquid crystal display; the shoulder further has a second planar surface perpendicular to the lower supporting surface; the height of the second planar surface is equal to or greater than the thickness of a plurality of optical films; and the second planar surface and the lower supporting surface commonly define a receiving space for receiving the optical films of the liquid crystal display.

9. The manufacturing method of the plastic housing according to claim 8, characterized in that: the second planar surface is further formed with an engaging block, which is protruded on the second planar surface; and a distance between the engaging block and the lower supporting surface is equal to the height of the second planar surface, and is equal to or greater than the thickness of the optical films, so that the optical films can be tightly engaged in the receiving space commonly defined by the second planar surface and the lower supporting surface.

10. The manufacturing method of the plastic housing according to claim 8, characterized in that: the optical films include a diffusion sheet, a prismatic lens, a microlens sheet, a lenticular lens or a combination thereof.

11. The manufacturing method of the plastic housing according to claim 10, characterized in that: the thickness of each of the optical films is 0.2 to 0.3 millimeters.

12. A liquid crystal display, comprising a plurality of optical films, a panel and a plastic housing, characterized in that:
the plastic housing is an integral plastic housing, comprising a lower supporting surface and two side frames being oppositely disposed on the lower supporting surface; each of the two side frames is formed with a shoulder on an inner sidewall thereof; the shoulder has a first planar surface parallel to the lower supporting surface, a panel is placed on the first planar surface, and two ends of the panel are separately clamped by the inner sidewalls of the two side frames; the shoulder further has a second planar surface perpendicular to the lower supporting surface; the height of the second planar surface is equal to or greater than the thickness of a plurality of optical films; and the optical films are installed in a receiving space commonly defined by the second planar surface and the lower supporting surface.

13. The liquid crystal display according to claim 12, characterized in that: the second planar surface is further formed with an engaging block, which is protruded on the second planar surface; and a distance between the engaging block and the lower supporting surface is equal to the height of the second planar surface, and is equal to or greater than the thickness of the optical films, so that the optical mould can be tightly engaged in the receiving space commonly defined by the second planar surface and the lower supporting surface.

14. The liquid crystal display according to claim 12, characterized in that: the optical films include a diffusion sheet, a prismatic lens, a microlens sheet, a lenticular lens or a combination thereof.

15. The liquid crystal display according to claim 14, characterized in that: the thickness of each of the optical films is 0.2 to 0.3 millimeters.
